(19) United States
(12) Patent Application Publication
(10) Pub. No.: US 2011/0290175 A1
(43) Pub. Date: Dec. 1, 2011

(54) Multi-Chamber CVD Processing System

(75) Inventors: Ajit Paranjpe, Basking Ridge, NJ (US); Eric A. Armour, Pennington, NJ (US); William E. Quinn, Whitehouse, NJ (US)

(73) Assignee: VEECO INSTRUMENTS, INC., Plainview, NY (US)

(21) Appl. No.: 13/185,450

(22) Filed: Jul. 18, 2011

Related U.S. Application Data
(63) Continuation-in-part of application No. 12/479,834, filed on Jun. 7, 2009.

(51) Int. Cl. C30B 25/02; C30B 25/08; C30B 25/12

(52) U.S. Cl. 117/85; 117/88; 117/101; 118/712; 118/719

(57) ABSTRACT

A multi-chamber CVD system includes a plurality of substrate carriers where each substrate carrier is adapted to support at least one substrate. A plurality of enclosures are each configured to form a deposition chamber enclosing one of the plurality of substrate carriers to maintain an independent chemical vapor deposition process chemistry for performing a processing step. A transport mechanism transports each of the plurality of substrate carriers to each of the plurality of enclosures in discrete steps that allow processing steps to be performed in the plurality of enclosures for a predetermined time. In some embodiments, the substrate carrier can be rotatable.

### RELATED APPLICATION SECTION

This application is a continuation-in-part of U.S. patent application Ser. No. 12/479,834, filed Jun. 7, 2009, entitled “Continuous Feed Chemical Vapor Deposition System.” The entire specification of U.S. patent application Ser. No. 12/479,834 is incorporated herein by reference.

The section headings used herein are for organizational purposes only and should not to be construed as limiting the subject matter described in the present application in any way.

### INTRODUCTION

Chemical vapor deposition (CVD) involves directing one or more gases containing chemical species onto a surface of a substrate so that the reactive species react and form a film on the surface of the substrate. For example, CVD can be used to grow compound semiconductor material on a crystalline semiconductor substrate. Compound semiconductors, such as III-V semiconductors, are commonly formed by growing various layers of semiconductor materials on a substrate using a source of a Group III metal and a source of a Group V element. In one CVD process, sometimes referred to as a chloride process, the Group III metal is provided as a volatile halide of the metal, which is most commonly a chloride, such as GaCl₂, and the Group V element is provided as a hydride of the Group V element.

Another type of CVD is metal organic chemical vapor deposition (MOCVD). MOCVD uses chemical species that include one or more metal organic compounds, such as alkyls of the Group III metals, such as gallium, indium, and aluminum. MOCVD also uses chemical species that include hydrides of one or more of the Group V elements, such as NH₃, AsH₃, PH₃ and hydrides of antimony. In these processes, the gases are reacted with one another at the surface of a substrate, such as a substrate of sapphire, Si, SiC, SiGe, AlSiC, GaAs, InP, InAs or GaP, to form a III-V compound of the general formula InₓGa_{Y}Al_{Z}N_{A}As_{B}P_{C}Sb_{D}, where X+Y+Z equals approximately one, and A+B+C+D equals approximately one, and each of X, Y, Z, A, B, and C can be between zero and one. In some instances, bismuth may be used in place of some or all of the other Group III metals. Many compound semiconductors, such as GaAs, GaN, GaAlAs, InGaAsSb, InP, AsP, ZnSe, ZnTe, HgCdTe, InAsSbP, InGaN, AlGaN, SiGe, SiC, ZnO and InGaAlP, have been grown by MOCVD.

Another type of CVD is known as Halide Vapor Phase Epitaxy (HVPE). In one HVPE process, Group III nitrides (e.g., GaN, AN) are formed by reacting hot gaseous metal chlorides (e.g., GaCl or AlCl) with ammonia gas (NH₃). The metal chlorides are generated by passing hot HCl gas over the hot Group III metals. All reactions are done in a temperature controlled quartz furnace. One feature of HVPE is that it can have a very high growth rate, up to 100 μm per hour for some state-of-the-art processes. Another feature of HVPE is that it can be used to deposit relatively high quality films because films are grown in a carbon-free environment and because the hot HCl gas provides a self-cleaning effect.

### SUMMARY OF THE INVENTION

The present teaching relates to a multi-chamber CVD processing system which comprises a plurality of substrate carriers, each substrate carrier adapted to support at least one substrate; a plurality of enclosures, each of the plurality of enclosures configured to form a deposition chamber enclosing one of the plurality of substrate carriers to maintain an independent environment for performing a processing step; and a transport mechanism that transports each of the plurality of substrate carriers to each of the plurality of enclosures in discrete steps that allows processing steps to be performed in the plurality of enclosures for a predetermined time. The multi-chamber CVD system can additionally comprise a plurality of heaters, each of the plurality of heaters corresponding to each of the plurality of enclosures. The multi-chamber CVD system can additionally comprise an in-situ measurement device placed in at least one of the plurality of enclosures. The transport mechanism can additionally comprise a plurality of heaters, each of the plurality of heaters being proximate to each of the plurality of substrate carriers. The transport mechanism can transport each of the plurality of substrate carriers in a linear or non-linear path using, for example, a rail, track or conveyor system, which can also include belts, push-rods, and magnetically coupled drives, such as magnetic linear motors. In some embodiments, at least one of the plurality of substrate carriers in the multi-chamber CVD system is a rotatable.

The present teaching also relates to a multi-chamber CVD process system which comprises a plurality of substrate carriers, where each substrate carrier is adapted to support at least one substrate; a plurality of enclosures, each of the plurality of enclosures configured to form a deposition chamber enclosing one of the plurality of substrate carriers to maintain an independent environment for performing a processing step; a plurality of heaters that each heat a corresponding one of the plurality of substrates to a desired process temperature for performing the processing steps; and a transport mechanism that transports each of the plurality of substrate carriers to each of the plurality of enclosures in discrete steps that allows processing steps to be performed in the plurality of enclosures for a predetermined time. The transport mechanism can additionally comprise a plurality of heaters which are proximate to each susceptor. The heaters can be positioned inside the deposition chamber or correspondingly translated with the substrate carrier. In some embodiments, at least one of the plurality of substrate carriers in the multi-chamber CVD system is a rotatable.

The present teaching also relates to a method of forming multiple epitaxial layers on a substrate using a multi-chamber chemical vapor deposition system where the method comprises enclosing a first substrate carrier comprising at least one substrate at a first location to form a first deposition chamber that maintains a first independent environment; growing a first epitaxial layer on the at least one substrate in the first deposition chamber at the first location with the first independent environment; transporting the first substrate carrier after the first epitaxial layer is grown to a second location and enclosing the first substrate carrier to form a second deposition chamber that maintains a second independent environment; and growing a second epitaxial layer on top of the first epitaxial layer in the second deposition chamber at the second location with the second independent environment. The method can further comprise enclosing a second substrate carrier comprising at least one substrate at the first location to form the first deposition chamber that maintains the first independent environment; and growing the first epitaxial layer on the at least one substrate on the second substrate carrier in the first deposition chamber at the first location with the first independent environment.

The present teaching also relates to a multi-chamber chemical vapor deposition system which comprises a means for enclosing a plurality of substrate carriers which support at least one substrate at a plurality of fixed locations to form a plurality of deposition chambers that each maintain an independent environment; a means for growing an epitaxial layer on the at least one substrate supported by the plurality of substrate carriers in the plurality of deposition chambers that are each maintaining the independent environment; and a means for transporting the plurality of substrate carriers between the plurality of deposition chambers in discrete steps. In some embodiments, at least one of the plurality of substrate carriers in the multi-chamber chemical vapor deposition system is a rotatable.

Within the CVD processing systems described herein, the substrate carriers can comprise, for example, a susceptor and substrate carrier assembly, a susceptorless carrier, or a planetary carrier.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale, emphasis instead generally being placed upon illustrating principles of the teaching. The drawings are not intended to limit the scope of the Applicant's teaching in any way.

FIG. 1 illustrates a side-view of one embodiment of a multi-chamber CVD system according to the present teaching

FIG. 2A illustrates a side-view of one embodiment of a deposition chamber according to the present teaching where the deposition chamber is formed by moving an enclosure over a substrate carrier.

FIG. 2B illustrates a side-view of one embodiment of a deposition chamber according to the present teaching where the deposition chamber is formed by moving a substrate carrier into an enclosure.

FIG. 3A, FIG. 3B, FIG. 3C, and FIG. 3D show examples of different embodiments of the heaters useful in the present system.

FIG. 4 illustrates a side-view of the embodiment of the multi-chamber CVD system in FIG. 1 in a particular mode.

FIG. 5 illustrates a side-view of the embodiment of the multi-chamber CVD system in FIG. 1 in another particular mode.

FIG. 6 illustrates a side-view of an embodiment of the multi-chamber CVD system according to the present teaching in another particular mode.

FIG. 7A illustrates a side-view of one embodiment of a deposition chamber according to the present teaching where process gases are injected horizontally into the deposition chamber.

FIG. 7B illustrates a top-down view (in the A direction) of the deposition chamber shown in FIG. 7A.

FIG. 8 illustrates a perspective top-view of another variation of a horizontal flow gas injector CVD system according to the present teaching.

FIG. 9 illustrates a side-view of another variation of a horizontal flow gas injector CVD system according to the present teaching.

### DESCRIPTION OF VARIOUS EMBODIMENTS

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the methods of the present teachings may be performed in any order and/or simultaneously as long as the teaching remains operable. Furthermore, it should be understood that the apparatus and methods of the present teachings can include any number or all of the described embodiments as long as the teaching remains operable.

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

The present teaching relates to methods and apparatus for reactive gas phase processing, such as CVD, MOCVD, and HYPE. In reactive gas phase processing of semiconductors materials, semiconductor substrates or substrates are mounted in a substrate carrier inside a reaction chamber. A gas distribution injector or injector head is mounted facing towards the substrate carrier. The injector or injector head typically includes a plurality of gas inlets that receive a combination of gases. The injector or injector head provides the combination of gasses to the reaction chamber for chemical vapor deposition. Many gas distribution injectors have showerhead devices spaced in a pattern on the head. The gas distribution injectors direct the precursor gases at the substrate carrier in such a way that the precursor gases react as close to the substrates as possible, thus maximizing reaction processes and epitaxial growth at the substrate surface.

Some gas distribution injectors provide a shroud that assists in providing a laminar gas flow during the chemical vapor deposition process. Also, one or more carrier gases can be used to assist in providing a laminar gas flow during the chemical vapor deposition process. The carrier gas typically does not react with any of the process gases and does not otherwise affect the chemical vapor deposition process. A gas distribution injector typically directs the precursor gases from gas inlets of the injector to certain targeted regions of the reaction chamber where substrates are processed.

For example, in MOCVD processes, the injector introduces combinations of precursor gases including metal organics and hydrides, such as ammonia or arsine into a reaction chamber through the injector. A carrier gas, such as hydrogen, nitrogen, or inert gases, such as argon or helium, is often introduced into the reactor through the injector to aid in maintaining laminar flow at the substrate carrier. The precursor gases mix in the reaction chamber and react to form a film on a substrate. Many compound semiconductors, such as GaAs, GaN, GaAlAs, InGaAsSb, InP, ZnSe, ZnTe, HgCdTe, InAsSbP, InGaN, AlGaN, SiGe, SiC, ZnO and InGaAlP, have been grown by MOCVD.

In both MOCVD and HVPE processes, the substrate is maintained at an elevated temperature within a reaction chamber. The process gases are typically maintained at a relatively low temperature of about 50-60° C. or below, when they are introduced into the reaction chamber. As the gases reach the hot substrate, their temperature, and hence their available energy for reaction, increases.

The most common type of CVD reactor is a rotating disc reactor. Such a reactor typically uses a disc-like substrate carrier. The substrate carrier has pockets or other features arranged to hold one or more substrates to be treated. The carrier, with the substrates positioned thereon, is placed into a reaction chamber and held with the substrate-bearing surface of the carrier facing in an upstream direction. The carrier is rotated, typically at rotational velocities of several hundred revolutions per minute, about an axis extending in the upstream to downstream direction. The rotation of the substrate carrier improves uniformity of the deposited semiconductor material. The substrate carrier is maintained at a desired elevated temperature, which can be in the range of about 350° C. to about 1,600° C. during this process.

While the carrier is rotated about the axis, the reaction gases are introduced into the chamber from a flow inlet element above the carrier. The flowing gases pass downwardly toward the carrier and substrates, preferably in a laminar plug flow. As the gases approach the rotating carrier, viscous drag impels them into rotation around the axis so that in a boundary region near the surface of the carrier, the gases flow around the axis and outwardly toward the periphery of the carrier. As the gases flow over the outer edge of the carrier, they flow downwardly toward exhaust ports positioned below the carrier. Most commonly, MOCVD processes are performed with a succession of different gas compositions and, in some cases, different substrate temperatures, to deposit a plurality of layers of semiconductor having differing compositions as required to form a desired semiconductor device.

Other types of CVD or MOCVD reactors include disk-like substrate carriers which do not rotate in the reactor during deposition and/or epitaxial layer growth.

The apparatus and methods of the present teaching relate to linear and in-line CVD processing system. The term “in-line” as used herein in connection with the transport of substrates refers to the transport of substrates in a plane from one chamber of a multi-chamber CVD system to another chamber of a multi-chamber CVD system. The transporting in-line is not necessary transporting in a straight line. The transporting can be linear or can be along a curve. For example, commercially available in-line systems have been arranged in several parallel lines, in a circle, in a U-shaped arrangement, or vertically stacked in a linear or U-shaped arrangement. Furthermore, the transporting can be along a closed rail or track with the same starting and ending point or can be in only one direction only. The term “in line” when referring to transport mechanisms according to the present teaching can include a conveyor-type transport mechanism, such as a conveyor belt that includes two or more rollers with a continuous belt that rotates about them. Other types of system processing architectures useful in the present invention include those found in U.S. Provisional Patent Application Ser. No. 61/237,141, filed Aug. 26, 2009, entitled “System for Fabricating a Pattern on Magnetic Recording Media”, the contents of which are hereby incorporated herein by reference.

Known apparatus and methods for CVD, such as MOCVD and HYPE, are not suitable for linear and in-line processing systems. The apparatus and methods of the present teaching can perform any type of CVD, such as MOCVD and HYPE. In one aspect of the present teaching, the apparatus and methods of the present teaching use an in-line discontinuous transport mechanism. The term “discontinuous transport mechanism” as referred to herein is a transport mechanism that transports substrates and/or substrate carriers in discontinuous steps. That is, the substrates and/or the substrate carries are transported from one CVD processing chamber in the multi-chamber CVD processing system to another CVD processing chamber in the multi-chamber CVD processing system and then the substrates and/or substrate carriers are positioned in their respective CVD process chamber at fixed location for a predetermined time while a CVD process step is performed.

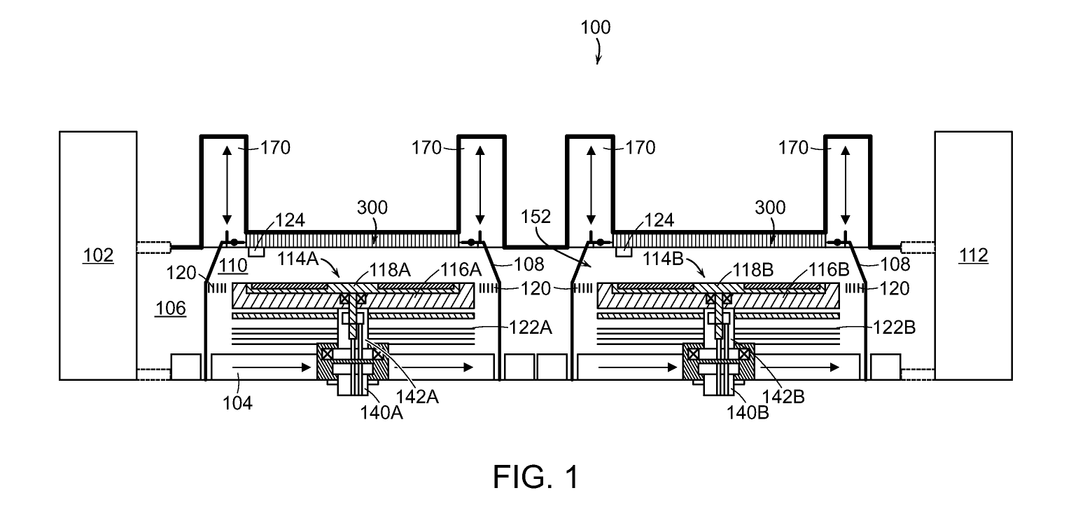

FIG. 1 illustrates a side-view of one embodiment of a multi-chamber CVD system 100 according to the present teaching. The CVD system 100 includes a substrate loading station 102, such as the automated mechanical handling system that is manufactured by Veeco Instruments Inc. of Plainview, NY. The substrate loading station 102 typically opens to atmospheric pressure where substrates are inserted for CVD processing. A gate valve interfaces the substrate loading station 102 to an input of the substrate transport mechanism 104 located in a housing 106 containing a plurality of enclosures 108 that form deposition chambers 110 and 152 in the multi-chamber CVD system 100. At the top of deposition chambers 110 and 152 is gas flow flange 300. Gas flow flange 300 is a flow inlet element typically found in MOCVD or CVD process chambers. Such gas flow flanges typically have at least one reactive gas source, and in some instances a carrier gas, as well as manifolds and baffles and gas distribution chambers to ensure proper gas flow towards the direction of the substrate. An example of a suitable gas flow flange can be found in U.S. Patent Publication No. 2010/0143588. At the bottom of deposition chambers 110 and 152 is an orifice 160 which can be outfitted with appropriate pumps, gas sources, and exhaust manifolds so as to pressurize or evacuate deposition chambers 110 and 152, depending upon the process conditions or if deposition chambers 110 and 152 are to be purged of reactive gases so that the enclosures 108 can be moved into recess 170 and the spindles 140A and 140B translate to its next stop within system 100. Spindles 140A and 140B can be connected to the substrate transport system 104 by a variety of connectors known to those skilled in the art, such as, for example and not limited to , mechanical connectors (for example, nut and bolt), electro-mechanical (for example, solenoid pin), and magnetic couplings. Other substrate transport systems and spindles described herein can be connected in a similar fashion.

The processed substrates are removed from the multi-chamber CVD system 100 with a substrate unloading station 112 positioned at the end of the housing 106 containing the plurality of enclosures 108. The substrate unloading station 112 can also be the automated mechanical handling system that is manufactured by Veeco Instruments Inc. of Plainview, NY. The substrate unloading station 112 typically opens to atmospheric pressure where substrates are removed after CVD processing. A gate valve interfaces the substrate unloading station 112 to the output of the substrate transport mechanism 104 located in the housing 106 containing the plurality of enclosures 108 that form deposition chambers 110 and 152 in the multi-chamber CVD system 100. Both the substrate loading station 102 and the substrate unloading station 112 can also be pump-purged independently from the rest of the system.

There are a plurality of substrate carriers 114A and 114B, which are movable along the transport mechanism 104. The multi-chamber CVD system shown in FIG. 1 illustrates only two substrate carriers to simply the figure. In practice, a multi-chamber CVD system according to the present teaching will include numerous substrate carriers 114A and 114B that are enclosed in enclosures 108 to form numerous deposition chambers 110 and 152. Some CVD systems are configured to have one deposition chamber for each layer grown on the substrate.

The plurality of substrate carriers 114A and 114B interface with the substrate loading station 102 so that substrates can be transferred from the substrate loading station 102 to the adjacent substrate carriers 114A and 114B. Each of the plurality of substrate carriers 114A and 114B includes a susceptor 116A and 116B, respectively, and substrate carrier assembly 118A and 118B, respectively. The susceptor 116A and 116B includes a base structure made of a material having high thermal conductivity at high temperature so that thermal energy is easily transferred from heaters 122A and 122B to the substrates. The substrate carrier assembly 118A and 118B includes a platen for holding at least one substrate, such as a semiconductor wafer, during growth of epitaxial layers with CVD and a spindles 140A and 140B which supports the susceptor 116A and 116B and in some instances as disclosed herein, heaters 122A and 122B by using heater supports 142A and 142B, which can be, for example, a single support pole or which can be a sleeve around spindles 140A and 140B. In other embodiments, a susceptorless wafer carrier can be used in place of susceptor 116A and 116B and platen, where heat is transferred from heaters 122A and 122B directly to the bottom of the wafer carrier, which is made a material having high thermal conductivity at high temperature so that thermal energy is easily transferred from heaters 122A and 122B to the substrates. One type of susceptorless wafer carrier is described in U.S. Pat. No. 6,685,774. In many embodiments, each of the plurality of substrate carriers 114A and 114B comprises a platen that supports a plurality of substrates which are simultaneously processed.

The multi-chamber CVD system according to the present teaching includes a plurality of heaters 122A and 122B for controlling the temperature at the growth surfaces of substrates positioned in each of the plurality of deposition chambers 110 and 152 to maintain a desired growth temperature. One of the plurality of heaters 122A and 122B is positioned in thermal contact with each of the plurality of substrate carriers 114A and 114B. There are many possible types of heaters that can be used to control the temperature at the growth surface of each of the plurality of deposition chambers 110 and 152. Heaters 122A and 122B can be positioned inside and/or outside of the enclosures 108.

For example, the plurality of heaters 122A and 122B can be resistive-type heaters, such as graphite heaters. Such heaters will typically be placed inside of the deposition chambers 110 and 152 proximate to and in thermal contract with each of the plurality of substrate carriers 114A and 114B. In one specific embodiment, three banks of linear resistive heaters are arranged in two halves with a gap between the two halves for passing the spindles supporting the plurality of substrate carriers 114A and 114B. In addition, the plurality of heaters 122A and 122B can be RF heaters that transfer RF energy to the growth surface of each of the substrates in the plurality of deposition chambers 110 and 152. Such heaters have RF induction coils positioned inside or outside of the enclosures 108. Radiant energy from lamps, for example, quartz lamps, may also be used for heating or fine tuning of the temperature profile.

Some multi-chamber CVD systems according to the present teaching include stationary resistive heater elements that are shaped to define a gap or passage for the plurality of substrate carrier 114A and 114B to be transported into and out of the plurality of enclosures 108. For example, in one specific embodiment, stationary resistive heaters are formed to define two semi-circular heater elements that define a passage for the plurality of enclosures 108 to pass into and out of the plurality of deposition chambers 110 and 152. The passage is wide enough so that spindles supporting the plurality of substrate carriers 114A and 114B pass freely through the passage between the two semi-circular heater elements when the plurality of substrate carriers are being transported with the transport mechanism 104.

Other multi-chamber CVD systems according to the present teaching include a first heater that includes stationary resistive heater elements shaped to define a gap or passage for the plurality of substrate carrier 114A and 114B to be transported into and out of the plurality of enclosures 108 and a second heater that is attached to the substrate carriers 114A and 114B. These heaters can be independently controllable. The heater that is attached to the substrate carriers 114A and 114B can be used to heat the substrates or to maintain a desired temperature of the substrates while they are being transported to the next deposition chamber. Using two heaters can increase the throughput by reducing the time that it takes the substrates to achieve the desired process temperature.

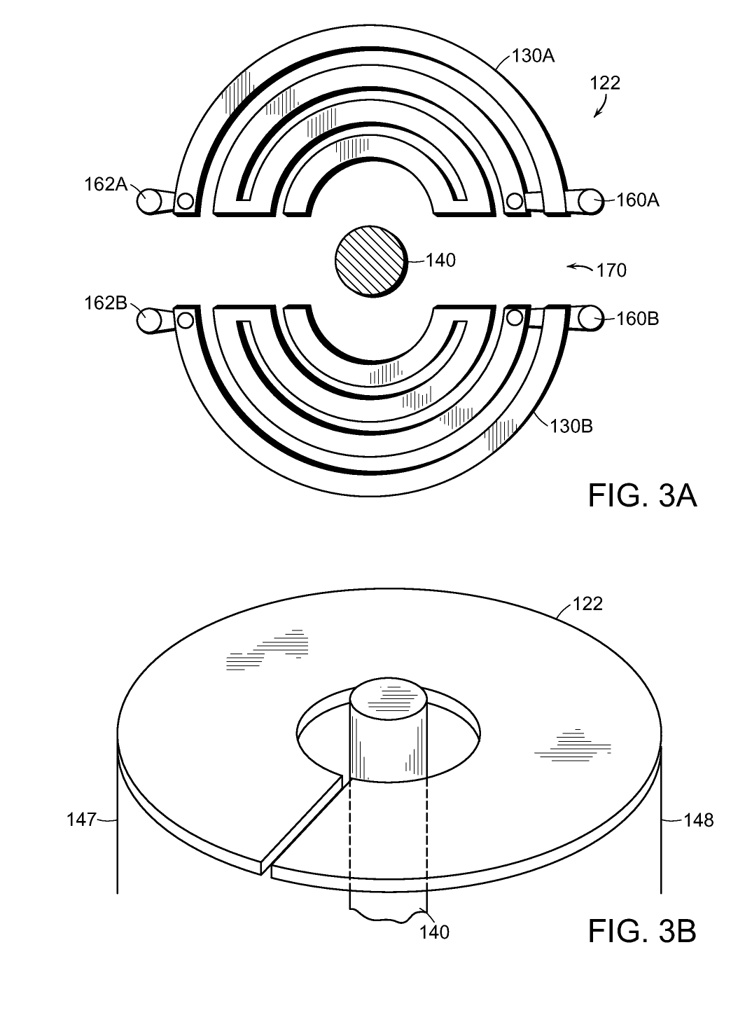

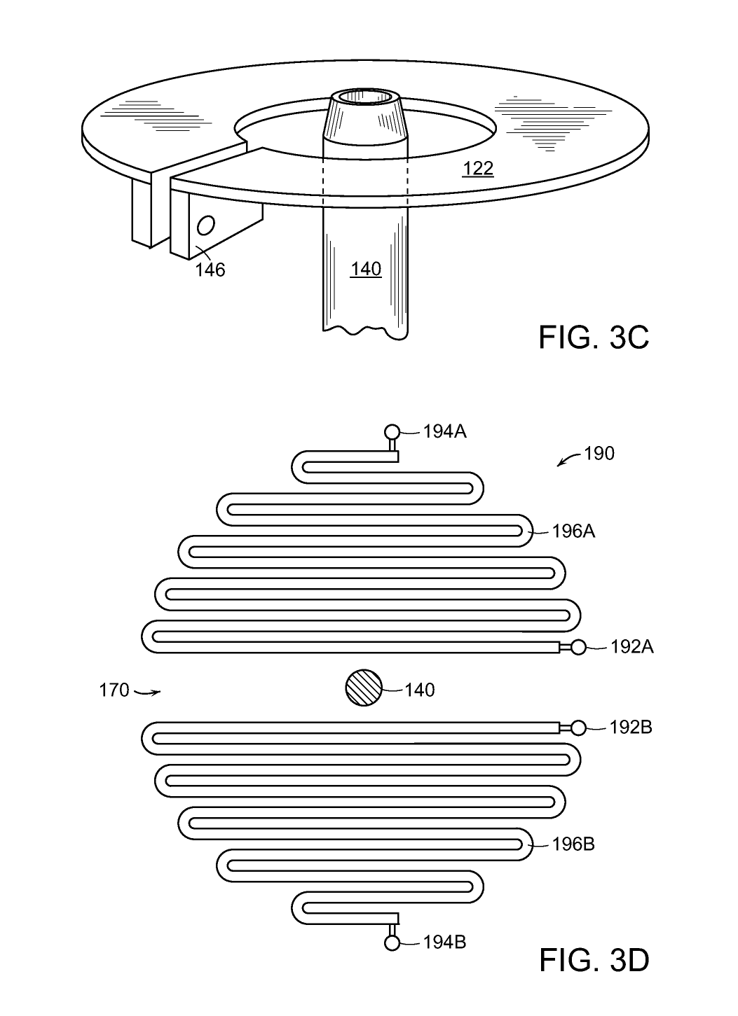

FIG. 3A shows an example (top view) of a heater 122 which has a gap between two halves through which the spindle can pass. Heater element 130A and heater element 130B are connected to any non-moving surface within chambers 110 and 152 by brackets 160A & 162A and 160B & 162B, respectively. Appropriate wiring and other heater controls also pass through the appropriate brackets. Gap 170 is sufficiently wide enough to allow spindles 140A and 140B to move through as it translates through the different chambers within the system.

FIG. 3B and FIG. 3C show examples of a heater 122 which can be connected to spindle 140 using heater support 142 (not shown). In FIG. 3B, supports 147 and 148 connect heater 122 to another support (not shown). Appropriate wiring and other controls can also flow through the supports 147 and 148. In FIG. 3C, bracket 146 connects heater 122 to a heater support (not shown) with appropriate wiring and other controls passing through heater support 142 (not shown) to bracket 146.

FIG. 3D shows another example (top view) of a heater 190 which has a gap between two halves through which the spindle can pass. Heater element 196A and heater element 196B are connected to any non-moving surface within chambers 110 and 152 by brackets 192A & 194A and 192B & 194B, respectively. Appropriate wiring and other heater controls also pass through the corresponding brackets. Gap 170 is sufficiently wide enough to allow spindles 140A and 140B to move through as it translates through the different chambers within the system.

In another embodiment, the substrates themselves are used as a resistive heater. In this embodiment, the substrates are constructed of a material and with a thickness that results in a resistivity which is suitable for resistive heating. A power supply is electrically connected to the substrates. The current generated by the power supply is regulated so that the substrates are heated to the desired processing temperature. One skilled in the art will appreciate that other types of heaters can be used to heat the substrates 104. In addition, the multi-chamber CVD system according to the present teaching can include multiple types of heaters that can be positioned inside and/or outside of the deposition chambers 110 and 152 to heat the growth surfaces of the substrates to the desired processing temperatures.

In some embodiments of the present teaching, at least one of the plurality of substrate carriers 114A and 114B rotates the at least one substrate about an axis during processing. The rotation rate depends upon the specific process. For some processes, the rotation rate is up to 1,500 rpms. In other embodiments, at least one of the plurality of substrate carriers 114A and 114B translates the at least one substrate during processing. In yet other embodiments, at least one of the plurality of substrate carriers 114A and 114B rotates and translates the at least one substrate during processing. The substrate carriers could also remain stationary or translate linearly while one or more substrates are loaded on a planet that rotates about its axis. The substrate carrier may be round with substrates or planets arranged in various configurations on the carrier, or could be rectangular or square in cases where the carrier is not rotating. The carrier configuration is optimized for the substrate size being processed. In this manner, substrates that are round, square or rectangular and range in size from 2″ to 12″ typically may be processed by using the appropriately sized and configured carrier.

The plurality of enclosures 108 are each configured to form one of a plurality of deposition chambers 110 and 152 that enclose one of the plurality of substrate carriers 114A and 114B in order to maintain an independent environment. In the independent environment, the chemical vapor deposition process chemistry can be performed as a CVD processing step. In other instances in the independent environment, annealing or other non-chemical vapor deposition process chemistry steps can be performed. In some systems according to the present teaching, each of the plurality of deposition chambers 110 and 152 is designed and operated to perform one of a plurality of processing steps in a sequence of CVD processing steps. In other systems according to the present teaching, each of the plurality of deposition chambers 110 and 152 performs one or more processing steps, which may or may not be chemical vapor deposition process chemistry related.

In many embodiments, one or more of the plurality of enclosures 108 comprises a physical enclosure, such as a stainless steel enclosure or a glass bell jar. One skilled in the art will appreciate that numerous types of materials can be used to form the physical enclosures. In many embodiments, each of the plurality of enclosures 108 is fluid cooled to remove the heat generated during deposition. Conduits for water or other types of fluid cooling can be formed in or around the plurality of enclosures 108.

In other embodiments, at least one of the plurality of enclosures 108 comprises a gas curtain (or purge) which forms at least one boundary of the corresponding enclosure. In these embodiments, adjacent gas curtains can be separated by a region that is under vacuum. The regions under vacuum remove process gasses between adjacent deposition chambers 110 and 152 so that separate process chemistries are maintained in each of the plurality of deposition chambers 110 and 152. The gas curtain (purge) can be H₂, N₂, NH₃ and/or any combination of them for typical GaN-type reactors. For other Group III/V type reactors, gases such as hydrides (for example, AsH₃ or PH₃) are useful. In order to reduce process cross-talk between enclosures, the pressure within the enclosure is equilibrated to the pressure of the overall chamber before the enclosure is opened. Also gases may continue to flow through selected injectors located within each injector to maintain the gas ambient necessary to prevent untoward degradation of the substrate while the carrier is being transferred from one station to another station.

In other embodiments, one or more gas curtains are used between at least two of the plurality of enclosures 108. Such gas curtains can be used to prevent process gases used in one deposition chamber from entering into another deposition chamber so that separate process chemistries are maintained in each of the plurality of deposition chambers 110 and 152. In yet other embodiments, a gas purge can be used in areas between at least two of the plurality of deposition chambers 110 and 152. The gas purge can be used to remove residual process gasses from the substrates as they move through the gas purge to the next deposition chamber.

The enclosures could operate synchronously or asynchronously depending on the mode of operation. In a cascaded mode, a carrier can be moved into the last station after the carrier from the last station is removed and the process ripples through the stations. In another mode, all the carriers move synchronously from one station to the next. In yet another mode, the last station is unloaded, and then the remaining carriers index synchronously to the next station. Other operating modes are also possible in which carriers move bi-directionally between chambers, so that one set of contiguous chambers is used to complete one part of the growth, while another set is used to complete another part of the growth. The optimal operating mode is process and throughput dependent.

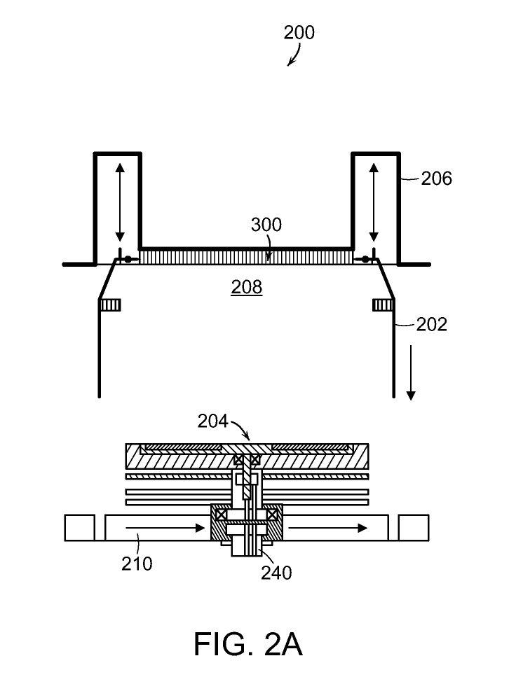

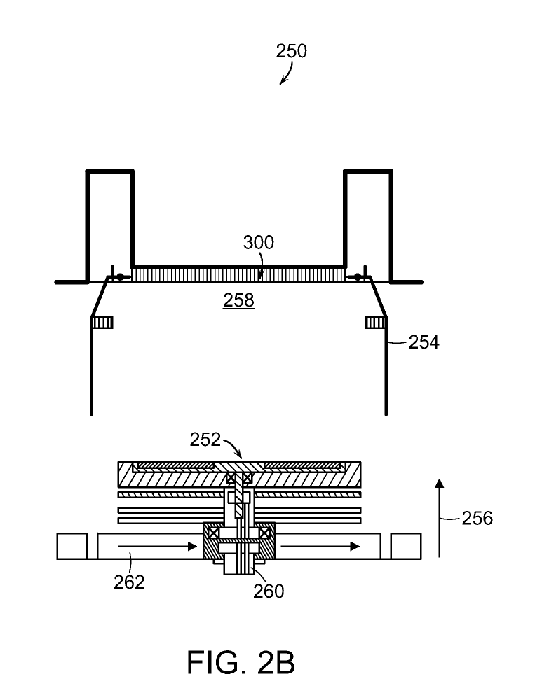

Each of the plurality of enclosures includes at least one gas input port that is coupled to at least one CVD process gas source so that the at least one gas input port injects at least one process gas into a respective deposition chambers 110 and 152. Gas flow flange 300 (FIGS. 2A and 2B) can include multiple gas input ports, including elevated temperature gas input ports, that can be used to inject CVD process gasses at temperatures above 75° C., that can be used with the multi-chamber CVD system according to the present teaching. The walls of the deposition chambers 110 and 152 can be heated to temperatures at or above the gas input port temperatures. The use of an elevated gas input port temperature allows the use of a relatively low substrate carrier rotation rate, a relatively high operating pressure, a relatively low flow rate, or some combination of desirable substrate carrier rotation rate, operating pressure, and gas flow rate. A different configuration of flow flange may be used within each enclosure. For example, these can include flow flanges configured for rotating disk reactors, close coupled showerhead reactors, cross flow planetary reactors, spatial or time modulated atomic layer epitaxy reactors, plasma or hot wire CVD reactors. In general, any reactor type that is compatible with an in-line implementation can be used. This allows a mix and match strategy in which the best suited reactor configuration is used for a particular growth step. Other types of reactor designs and substrate carrier designs that are useful in the present invention include those found in U.S. Provisional Patent Application Ser. No. 61/472,925 filed Apr. 7, 2011, entitled “Metal-Organic Vapor Phase Epitaxy System and Process”, the contents of which are hereby incorporated herein by reference.

The CVD process gasses can be located proximate to the multi-chamber CVD system 100 or can be located in a remote location. In many embodiments, a plurality of CVD gas sources, such as MOCVD gas sources, is available to be connected to the gas input ports of each of the plurality of deposition chambers 110 and 152 through a gas distribution manifold. The multi-chamber deposition system 100 can be easily configured to change the material structure being deposited by configuring the gas distribution manifold. The gas distribution manifold can be configured manually at the manifold or can be configured remotely by activating electrically operated valves and solenoids. Such an apparatus is well suited for research and flexible production environments because it can be easily reconfigured to change the deposited material structure. A shared assembly that provides the source gases for all the deposition chambers reduces the component count and cost while improving the consistency of source gas delivery to all the chambers. Such an assembly also allows expensive components, such as the in-line purifiers and filters to be shared. The system may also include a redundant station that is fully configured with the source gases that can be used as a spare station in the event that one of the stations fails. The redundant station will allows completion of all the process steps on the substrates presently loaded into the system. After the work in process (WIP) has been cleared, the affected station can be serviced. The transport system may include a means to bypass a failed station. Many other known system architectural features used to recover WIP when one of the stations fails can be implemented on this system.

The gas input ports can include a gas distribution nozzle which substantially prevents CVD gases from reacting until the CVD gases reach the surfaces of the plurality of substrates. Such gas distribution nozzle are configured to substantially prevent reactions of process gases from occurring away from the surface of the plurality of substrates in the deposition chambers 110 and 152, thereby preventing reaction by-products from embedding into the material deposited on the surfaces of the substrates being processed.

Also, each of the plurality of enclosures 108 includes at least one exhaust port to remove process gasses and reaction by-product gasses. In one embodiment, a ring-shaped exhaust port 120 is used to remove the process gasses and reaction by-product gasses. The at least one exhaust port 120 is coupled to an exhaust manifold. A vacuum pump is coupled to the exhaust manifold. The vacuum pump evacuates the exhaust manifold, thereby creating a pressure differential which removes the process gases and reaction by-product gasses from the plurality of deposition chambers 110 and 152. The exhaust ports are also configured to substantially prevent reactions of process gases from occurring away from the surface of the substrates in the deposition chambers 110 and 152, thereby preventing contamination of the deposited film. Depending on the gas load for each chamber, exhaust pumps can also be shared across multiple chambers provided there is no cross talk and the gases being exhausted are compatible with each other.

The transport mechanism 104 transports each of the plurality of substrate carriers 114A and 114B to each of the plurality of enclosures 108 in discrete steps that allow one or more processing steps to be performed in each of the plurality of enclosures 108 for a predetermined time. There are numerous means for transporting the plurality of substrate carriers 114A and 114B between the plurality of deposition chambers 110 and 152 in discrete steps and types of transport mechanisms according to the present teaching. For example, one type of transport mechanism according to the present teaching transports each of the plurality of substrate carriers 114A and 114B to each of the plurality of enclosures 108 on along a rail. Another type of transport mechanism according to the present teaching transports each of the plurality of substrate carriers 114A and 114B to each of the plurality of enclosures 108 on a track. Another type of transport mechanism according to the present teaching transports each of the plurality of substrate carriers 114A and 114B to each of the plurality of enclosures 108 with a conveyor type transport mechanism which, for example, uses a conveyor belt. In such transport systems, the rail, track, or conveyor systems, which can also include belts, push-rods, and magnetically coupled drives such as magnetic linear motors, can be designed to provide electrical power to the plurality of heaters 122A and 122B. In addition, in such transport systems, gas for pneumatically operated components, such as a rotation and/or translation assembly for the substrate carriers 114A and 114B can be provided from the rail, track, or conveyor systems.

The transport mechanism 104 shown in FIG. 1 moves the substrate carriers 114A and 114B in a path from the first enclosure to the second enclosure. In practice, there will typically be more than two substrate carriers 114A and 114B and enclosures 108 forming more than two deposition chambers 110 and 152. In various embodiments, the transport mechanism 104 can transport the substrate carriers in a straight linear direction or in a curved direction. The path that the transport mechanism transports the plurality of substrate carriers 114A and 114B can be an open path where the beginning and the end are at different physical locations with a straight or curved path between the beginning and end locations. Alternatively, the path that the transport mechanism 104 transports the plurality of substrate carriers 114A and 114B can be a closed path where the end of the path returns to the beginning of the path at a single location. In various embodiments, the closed path can be a non-linear path, for example and not limited to, a circular, oval, or a continuous track (for example, a tank tread) shaped.

In many embodiments, the transport mechanism 104 transports the substrate carriers 114A and 114B through the multi-chamber CVD deposition system in one direction. However, in other embodiments, the transport mechanism transports the substrate carriers 114A and 114B through the multi-chamber CVD deposition system in a first direction and then back through the multi-chamber CVD deposition system 100 in a second direction that is opposite to the first direction.

In the embodiment shown in FIG. 1, there is one substrate loading/unloading station 102 for inserting substrates into the multi-chamber CVD system 100 for processing and another substrate loading/unloading station 112 for removing processed substrates from the multi-chamber CVD system 100 after processing. In multi-chamber CVD systems 100 according to the present teaching that include a closed path, there can be a single substrate loading/unloading station that inserts substrates into the multi-chamber CVD system 100 for processing and that removes the processed substrates from the multi-chamber CVD system 100 after processing. In many embodiments, the substrate handling from the substrate loading/unloading stations 102, 112 is automated by robotic transport mechanisms. The loading and unloading stations can also function to either remove/add carriers from the system either for servicing or cleaning depending on the process requirements. For example, for MOCVD growth of As/P based materials, the carrier can be reused multiple times before cleaning is necessary, while cleaning after each deposition cycle is necessary for growth of GaN based materials. In addition, there can be one or more access stations or ports so that a user can access the platen, or wafer carrier, for removal/replacement and/or any other kind of adjustment.

Some multi-chamber CVD systems according to the present teaching include a transport mechanism comprising heaters that are positioned in close proximity to and integral with the substrate carriers 114A and 114B so that they are in thermal communication with the growth surfaces of the substrates. In such systems, the heaters 122A and 122B move along with the substrate carriers 114A and 114B. Power for resistive heaters that are integral with the substrate carriers 114A and 114B can be provided by the transport mechanism or can be provided by movable power cables.

In some systems according to the present teaching, at least one of the plurality of enclosures comprises at least one in-situ measurement device 124. In some systems, at least one of the plurality of enclosures can include a pyrometer that measures the temperature at the growth surfaces of the substrates positioned on the plurality of substrate carriers 114A and 114B during deposition. The resulting temperature measurement can be used to provide feedback to the heater controls circuit in order to maintain a desired growth temperature at the surface of the substrates. Also, in some systems, at least one of the plurality of enclosures 110 and 152 includes a reflectometer that measures thickness and/or growth rate of the deposited films. The reflectometer can provide a feedback signal that controls various deposition parameters, such as the temperature at the growth surface of the substrate, process gas flow rate, and pressure in the deposition chambers 110 and 152. Additional in-situ measurement devices 124 include other metrology tools commonly used in the semiconductor industry, including, for example, a deflectometer, which can be used for measuring curvature of a wafer during deposition, ellipsometer, photoluminescence spectrometer, reflectometer, combination pyrometer/reflectometer, a combined deflectometer/reflectometer/temperature tool, and electroluminescence spectrometer, and the like. The combination pyrometer/reflectometer can be one as disclosed, for example, in U.S. Pat. No. 6,349,270. The combined deflectometer, reflectometer, and temperature tool is available as a DRT-210 in-situ process monitor from Veeco Instruments.

FIG. 2A illustrates a side-view of one embodiment of a deposition chamber 200 according to the present teaching where the deposition chamber 200 is formed by moving an enclosure 202 over the substrate carrier 204. In this embodiment, the substrate carrier 204 is fixed in the vertical direction. For example, the substrate carrier 204 can be attached to a track, rail, or a conveyor-type transport system, which can also include belts, push-rods, and magnetically coupled drives such as magnetic linear motors, that transports the substrate carrier 204 (supported by spindle 240) in the horizontal direction through the multi-chamber deposition system 100 (FIG. 1). An actuator 206 translates the enclosure 202 in the vertical direction over the substrate carrier 204 to form the deposition chamber 208. The enclosure 202 interfaces with the transport system 210 to form a seal that contains the process chemistry in the deposition chamber 208. In some systems, the transport system 210 includes a gas seal formed on top of or into the top surface of the transport system 104. In one specific embodiment, the transport system 210 is a conveyor-type transport system that includes an o-ring type groove formed into the top surface where the bottom edge of the enclosure 202 directly contact the o-ring type groove to compress an o-ring, flange or gasket thereby forming a gas seal that substantially contains the process gasses in the deposition chamber 208.

FIG. 2B illustrates a side-view of one embodiment of a deposition chamber 250 according to the present teaching where the deposition chamber 250 is formed by moving a substrate carrier 252 into an enclosure 254. In this embodiment, the enclosure 254 is formed from non-movable front, back and side walls as well as a ceiling defined by gas flow flange 300. Enclosures such as enclosure 254 can be positioned at various locations within an assembly area and they are fixed in both the vertical and the horizontal directions so as to be plumb and level. An actuator 262 translates the substrate carrier 252 in a horizontal direction until substrate carrier 252 is appropriately aligned under enclosure 254. Then, actuator 256 moves substrate carrier 252 in a vertical direction into the enclosure 254 to form the deposition chamber 258. In some systems, the spindle 260 supporting the substrate carrier 252 is moved in the vertical direction into the enclosure 254 to form the deposition chamber 258. In these systems, the transport system 262 can be is a fixed location. Also, in some systems, the transport system 262 supporting the substrate carrier 252 is moved in the vertical direction so that the substrate carrier 252 is positioned into the enclosure 254 to form the deposition chamber 258. The enclosure 254 interfaces with the transport system 260 to form a seal that contains the process chemistry in the deposition chamber 258. The transport system 260 includes a gas seal, such as an o-ring, flange, or gasket seal formed on top of or into the top surface of the transport system 260 that substantially contains the process gasses.

Referring again to FIG. 1, one skilled in the art will appreciate that there are various other means for enclosing the plurality of substrate carriers 114A and 114B and configurations according to the present teaching where the plurality of enclosures 108 and the plurality of substrate carriers 114A and 114B interface to form the plurality of deposition chambers 110 and 152. For example, in one configuration, at least one of the plurality of enclosures 108 and a corresponding one of the plurality of substrate carriers 114A and 114B are both movable relative to each other in order to form at least one of the plurality of deposition chambers 110 and 152.

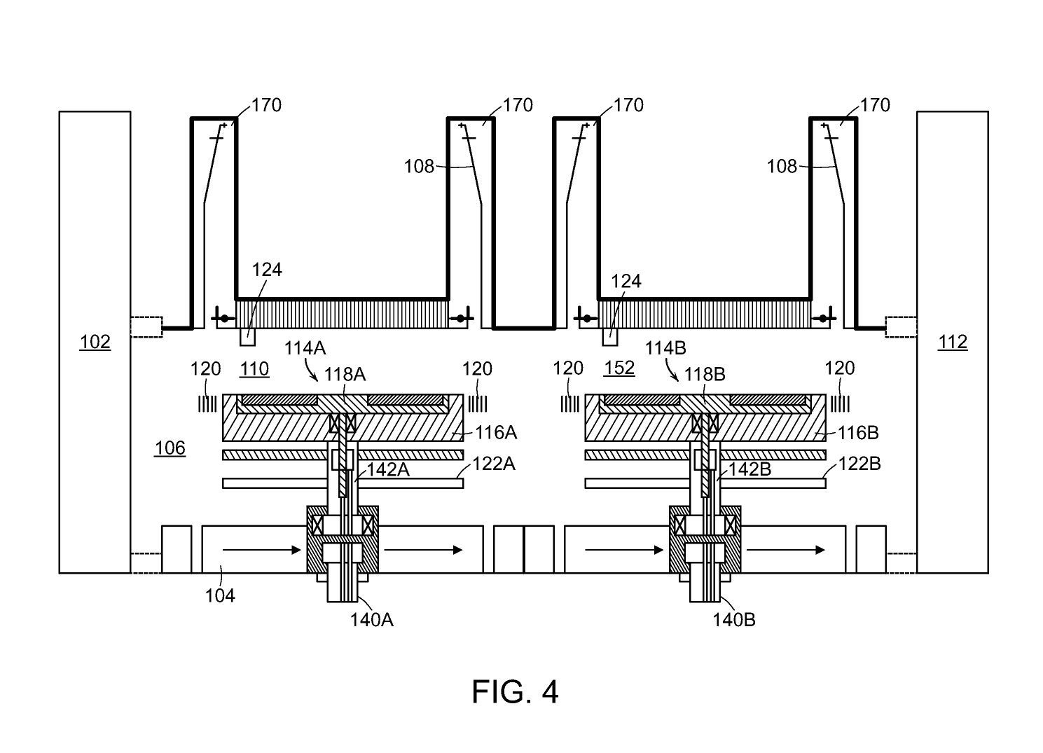

FIG. 4 shows a side-view of the embodiment shown in FIG. 1 where enclosures 108 are raised into recesses 170. In so doing, the chambers 110 and 152 have been purged of reaction gases and the pressure within house 106 has been equalized such that substrate carriers 114A and 114B, together with their respective susceptor 116A and 116B, substrate carrier assembly 118A and 118B, spindles 140A and 140B, and in some cases heaters 122A and 122B, together with heater supports 142A and 142B, can be moved by transport mechanism 104 in housing 106 to the next step in the desired process.

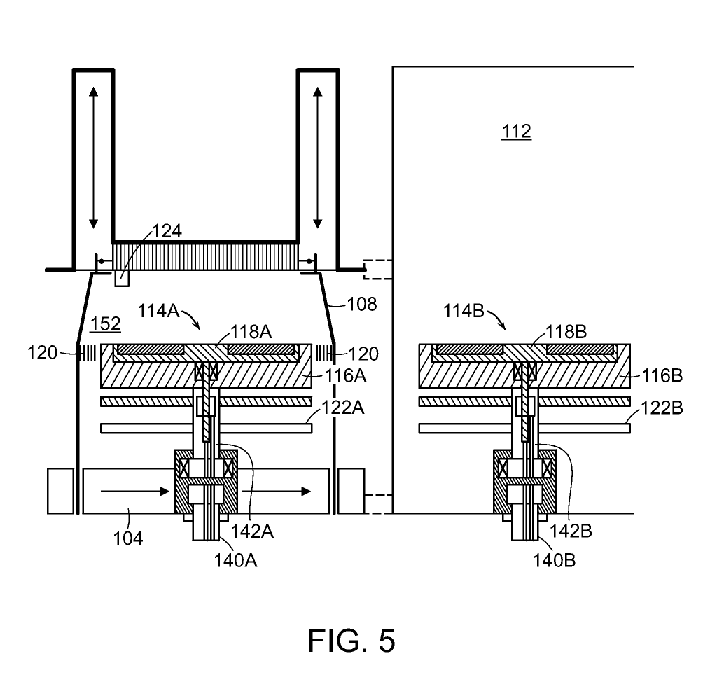

FIG. 5 illustrates a side-view of the embodiment of the multi-chamber CVD system in FIG. 1 in another particular mode. The side-view shows the substrate carrier 114B, together with its respective susceptor 116B, substrate carrier assembly 118B, spindle 140B, and in some cases heater 122B, together with heater support 142B, have been moved from deposition chamber 152 into substrate unloading station 112 and substrate carrier 114A, together with its respective susceptor 116A, substrate carrier assembly 118A, spindle 140A, and in some cases heater 122A, together with heater support 142A, have been moved from deposition chamber 110 into deposition chamber 152 for further processing.

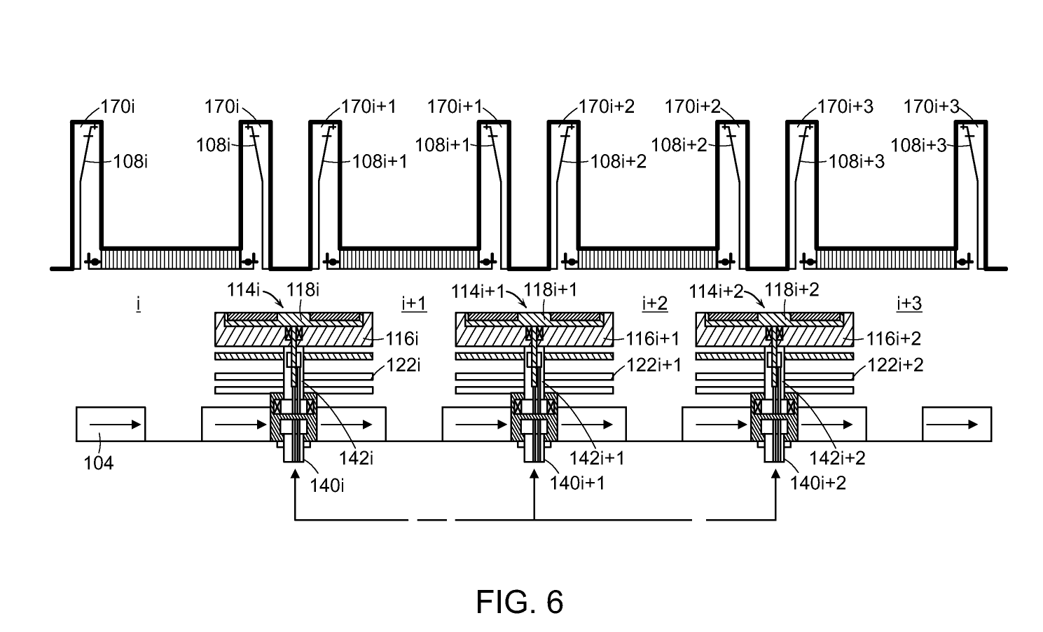

FIG. 6 shows a side-view of an embodiment of the present teaching where deposition chambers i, i+1, i+2, and i+3 have been purged of process gases and the pressure within those areas have been equilibrated. If desired, a gas curtain can be used between deposition chambers i and i+1, i+1 and i+2, and i+2 and i+3 if certain process conditions have to be maintained even though a carrier(s) is being moved out of one of the chambers. The plurality of substrate carriers 114i, 114i+1, and 114i+2, together with its respective susceptors 116i, 116i+1, and 116i+2, substrate carrier assemblies 118i, 118i+1, and 118i+2, spindles 140i, 140i+1, and 140i+2, and in some cases heaters 122i, 122i+1, and 122i+2, together with heater supports 142i, 142i+1, and 142i+2, are in the process from being moved by substrate transport mechanism 104 from deposition chambers i, i+1, and i+2, respectively. In this instance, enclosures 108i, 108i+1, 108i+2, and 108i+3 have been raised into their respective recesses 170i, 170i+1, 170i+2, and 170i+3. Once the substrate carriers 114 are properly aligned within its next deposition chamber; for example, substrate carrier 114i, together with susceptor 116i, substrate carrier assembly 118i, spindle 140i, and in some cases heater 122i, together with heater support 142i in chamber i+1, substrate carrier 114i+1, together with susceptor 116i+1, substrate carrier assembly 118i+1, spindle 140i+1, and in some cases heater 122i+1, together with heater support 142i+1 in chamber i+2, and substrate carrier 114i+2, together with susceptor 116i+2, substrate carrier assembly 118i+2, spindle 140i+2, and in some cases heater 122i+2, together with heater support 142i+2 in chamber i+3, enclosures 108i, 108i+1, 108i+2, and 108i+3 can be lowered out of recesses 170i, 170i+1, 170i+2, and 170i+3, to seal chambers i, i+1, i+2, and i+3 so that the next deposition step in the desired process can be performed.

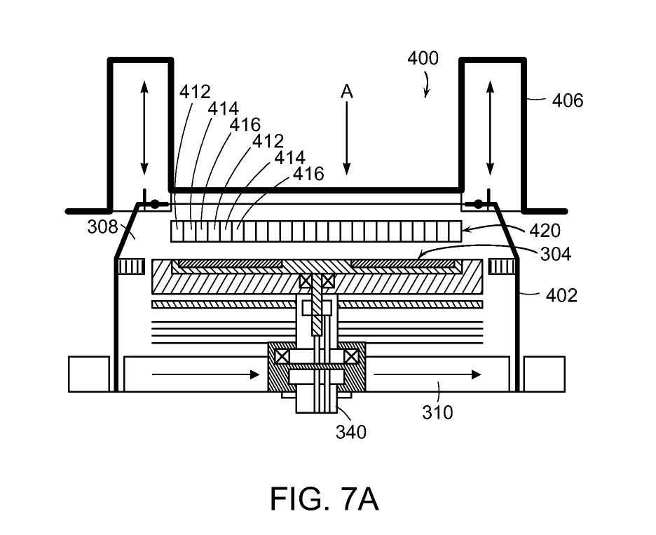

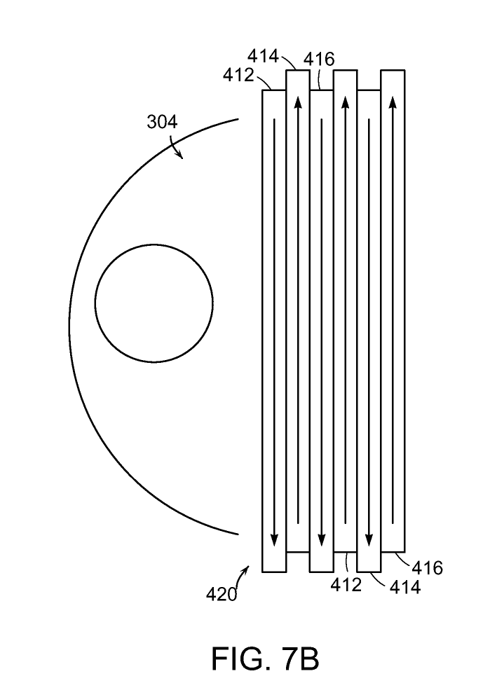

Process gases used in CVD processing systems according to the present teaching can be injected into the deposition chamber at any angle relative to the substrate carrier. Some CVD processing systems according to the present teaching inject the process gasses in a vertical direction that is substantially perpendicular to the surface of the substrate carrier. In these systems, the process gasses can be injected via the gas flow flange 300 as discussed herein. In other CVD process systems according to the present teaching, the process gases are injected in a horizontal direction where the gases flow in a direction that is substantially parallel to the surface of the substrate carrier. For example, one particular embodiments of the CVD processing system of the present teaching uses the horizontal or parallel gas injection system as depicted in FIGS. 7A and 7B.

FIG. 7A illustrates a side-view of one embodiment of a deposition chamber 400 according to the present teaching where the deposition chamber 400 is formed by moving an enclosure 402 over the substrate carrier 304. In this embodiment, the substrate carrier 304 is fixed in the vertical direction. For example, the substrate carrier 304 can be attached to a track, rail, or a conveyor-type transport system, which can also include belts, push-rods, and magnetically coupled drives such as magnetic linear motors, that transports the substrate carrier 304 (supported by spindle 340) in the horizontal direction through the multi-chamber deposition system 100 (FIG. 1). An actuator 406 translates the enclosure 402 in the vertical direction over the substrate carrier 304 to form the deposition chamber 308. The enclosure 402 interfaces with the transport system 310 to form a seal that contains the process chemistry in the deposition chamber 308. In some systems, the transport system 310 includes a gas seal formed on top of or into the top surface of the transport system 310. In one specific embodiment, the transport system 310 is a conveyor-type transport system that includes an o-ring type groove formed into the top surface where the bottom edge of the enclosure 402 directly contact the o-ring type groove to compress an o-ring, flange or gasket thereby forming a gas seal that substantially contains the process gasses in the deposition chamber 308.

Plate 420 contains a sufficient number of horizontally mounted tubes, for example tubes 412, 414, and 416 (not all tubes are identified), which can be placed in at an appropriate distance from the top of substrate carrier 308. Depending upon the arrangement within the chamber 308, tubes 412, 414, and 416 can each carry precursor gases or carrier gases, depending upon the MOCVD process being conducted in the chamber 308. In many instances, the tube carrying the inert gas will be placed between the tube carrying the carrier gas and the tube carrying the reactant gas. Holes or slits placed at the bottom of the tubes which face the top surface of substrate carrier 304 allow for the gases to flow towards the carrier 304.

FIG. 7B illustrates a top-down view (in the A direction as shown in FIG. 7A) of the deposition chamber shown in FIG. 7A (with many chamber parts removed). The top-down view of the deposition chamber shows one embodiment of plate 420 having tubes 412, 414, and 416. The arrows in the tubes 412, 414, and 416 show the general direction of gas flow therein. Those skilled in the art will appreciate that the directional flow of the gases can be changed depending upon the particular CVD process being preformed. The gases are discharged at an appropriate flow rate so that a desired epitaxial structure is grown on the wafer as the substrate carrier 304 rotates. To increase uniformity of epitaxial structure growth in the horizontal mode, the wafers would generally have to rotate about their axis in a planetary motion, where the wafer carrier on which the wafers are seated is rotated at a first rate while rotating the wafers around themselves (within their wafer seat) at a second rate, thereby creating planetary motion of the wafers in the wafer carrier. Such systems have been suggested using planetary gear systems, motor drivers rotating the wafer carrier and the wafers placed thereon. Those skilled in the art will appreciate that in certain circumstances, the substrate carrier 304 need not rotate.

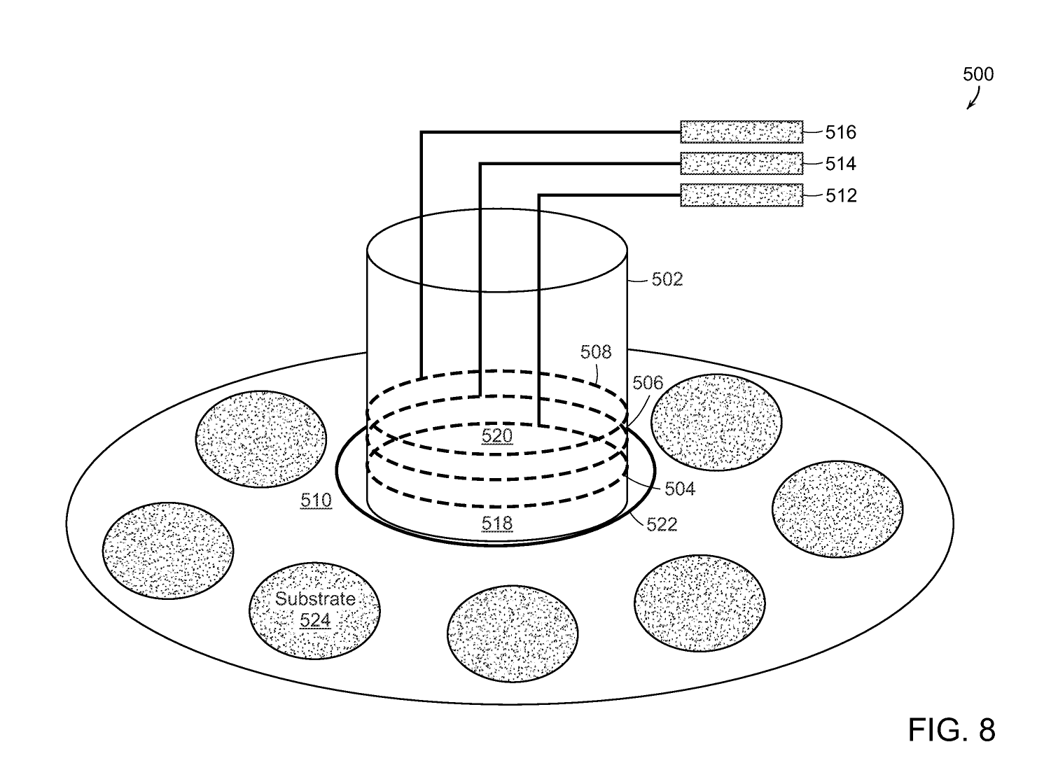

FIG. 8 illustrates a perspective top-view of another variation of a horizontal flow gas injector CVD system 500 according to the present teaching. The horizontal flow gas injector 500 can be used instead of or to supplement the gas flow provided by plate 420 and tubes 412, 414, and 416. The CVD system 500 includes circular gas injectors 504, 506, and 508 that inject precursor gases and inert gases in the plane of the platen 510 (i.e. horizontal flow into the process chamber). The first circular gas injector 504 is coupled to a first precursor gas source 512. The second circular gas injector 506 is coupled to an inert gas source 514. The third circular gas injector 508 is coupled to a second precursor gas source 516. In some instances, the first and third circular gas injectors 504, 508 are also coupled to a carrier gas source. The first circular gas injector 504 injects the first precursor gas in a first horizontal region 518. The third circular gas injector 508 injects the second precursor gas in a second horizontal region 520. A circular electrode 522 is positioned in the first horizontal region 518 so that first precursor gas molecules flow in contact with or proximate to the circular electrode 522. A physical or chemical barrier can be positioned between the first and the second horizontal regions 518, 520 in order to isolate the circular electrode 522 from the flow of the second precursor gas molecules.

In some instances, a baffle is positioned above the circular electrode 522 to substantially prevent the first precursor gas molecules from being thermally activated by the electrode 522 as they flow to the platen 510. In some instances, a gas curtain is used to separate the first and the second horizontal regions 518 and 520. In these systems, the second circular gas injector 506 injects inert gas between the first and the second horizontal regions 518, 520 in a pattern that substantially prevents the second precursor gas molecules from being activated by the circular electrode 522.

Methods of operating the CVD system 500 include injecting the first precursor gas with the first circular gas injectors 504 and injecting the second precursor gas with the third circular gas injectors 508. An inert gas is injected between the first and the second horizontal regions 518, 520 with the second circular gas injectors 506 to form a chemical barrier that prevents the second precursor gas molecules from being activated by the circular electrode 522. When the circular electrode 522 is powered by a power supply 220, the circular electrode 522 thermally activates first precursor gas molecules injected by the first circular gas injector 504 that flow in contact with or in close proximity to the circular electrode 522. The activated first precursor gas molecules and the second precursor gas molecules then flow over the surface of the substrates 524, thereby reacting to form an epitaxial layer. Purge gases can also be added as necessary (for example adjacent to the enclosure, or below the carrier) to keep these regions clear of parasitic deposition. Parasitic deposition can result in memory effects, particulate contaminations, flow blockage, and hazardous buildup, all of which are undesirable side-effects of CVD.

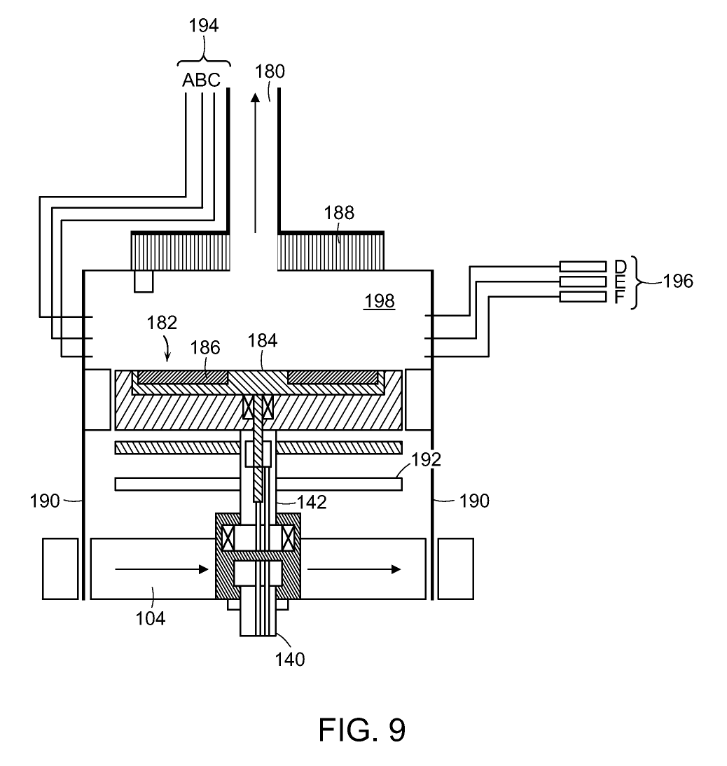

FIG. 9 illustrates a side-view of another variation of a horizontal flow gas injector CVD system according to the present teaching. Substrate carrier 182 includes a susceptor 186 and substrate carrier assembly 184. The substrate carrier 182, including susceptor 186 and substrate carrier assembly 184 are a planetary type carrier as discussed above and is typically made of a material having high thermal conductivity at high temperature so that thermal energy is easily transferred from heater 192 to the substrate. Spindle 140 supports susceptor 186 and spindle 140 is connected to transport mechanism 104 as discussed above. Chamber 198 is formed by moving substrate carrier 184 into an enclosure 190, which is formed from non-movable front, back and side walls as well as ceiling defined by a multi-zone showerhead 188. Enclosures such as enclosure 190 can be positioned at various locations within an assembly area and they are fixed in both the vertical and the horizontal directions so as to be plumb and level.

Enclosure 190 is shown in formed position. Similar to the embodiment disclosed in FIG. 2B, an actuator 104 translates the substrate carrier 182 in a horizontal direction until substrate carrier 182 is appropriately aligned under enclosure 190. Then, an actuator (not shown) moves substrate carrier 182 in a vertical direction into the enclosure 190 to form the deposition chamber 198. This system can also be moved in the additional manners as discussed above regarding FIG. 2B. Appropriate seals are put into place to prevent the leakage of process gases.

As part of this system, two different arrangements of process gases are shown and those skilled in the art will appreciate that there are many other arrangements for introducing the process gases into the chamber 198 in a horizontal fashion. Process gases can enter the chamber from arrangement 194, which contains three gases A, B, and C, at injectors 222. Exhaust 180 is located centrally over chamber 198 and is heated so as to prevent or reduce gas phase nucleation and helps avoid gas flow stagnation within the chamber. Process gases can also enter the chamber from arrangement 196, which contains three gases D, E, and F, at injectors 224. Injectors 222 or 224 are three zone peripheral type injectors which can provide controlled pre-mixing of the process gases, pre-heating of ammonia and other inert gases, and provide for radial flow of the gases from the chamber walls to the center of the chamber.

In some systems, it may be advantageous to have one precursor or carrier gas injected in a substantially perpendicular direction to the carrier surface and another precursor or carrier gas injected in a substantially parallel direction to the carrier surface.

One feature of the multi-chamber deposition system of the present teaching is that it can have very high throughput and, therefore, it is particularly suitable for mass production applications. High throughput can be obtained because each of the plurality of deposition chambers can be optimized for growing a particular layer structure to a particular thickness. In embodiments where the heaters 122A and 122B are fixed inside or proximate to the deposition chambers 110 and 152, the heaters 122A and 122B can be operated in a narrow temperature range that heats the growth surfaces of the substrates to their desired temperatures. In such systems, the time that it takes the growth surfaces to reach their desired growth temperatures can be minimized.

Another feature of the multi-chamber deposition system of the present teaching is that it is easily reconfigured to deposit different material layer structures and, there it is also very suitable for research and test environments. Another feature of the multi-chamber deposition system of the present teaching is that the system is highly repeatable because each of the substrates is exposed to substantially the same process conditions. The intrinsic process stability for each chamber is improved since each chamber is assigned to a subset of the process steps. Cross talk and memory effects, which can arise when disparate process steps sensitive to residual gas contamination from a prior step are performed in the same chamber, can be essentially avoided in the in-line architecture of the present teaching.

Yet another feature of the multi-chamber deposition system of the present teaching is that the system can be easily configured to perform in-situ characterization of the layers deposited on the substrates in the plurality of deposition chambers 110 and 152. One skilled in the art will appreciate that numerous types of in-situ measurement devices can be used to characterize the deposited films in the plurality of deposition chambers 110 or between the plurality of deposition chambers 110 and 152. Measurements may also be performed as substrates are transiting across multiple chambers by including a short section that includes in-situ measurement devices.

In general, a method of forming multiple epitaxial layers on a substrate using a multi-chamber chemical vapor deposition system according the present teaching includes enclosing a first rotatable substrate carrier comprising at least one substrate at a first location to form a first deposition chamber that maintains a first independent environment, which can be a chemical vapor deposition process chemistry environment. The enclosing the first substrate carrier to form the first deposition chamber can include moving an enclosure over the first substrate carrier to isolate the first chemical vapor deposition process chemistry inside the first deposition chambers. The enclosing the first substrate carrier to form the first deposition chamber can also include moving the first substrate carrier into an enclosure or chamber to isolate the first chemical vapor deposition process chemistry inside the first deposition chambers. Alternatively, the enclosing the first substrate carrier to form the first deposition chambers can include forming gas curtains to isolate the first chemical vapor deposition process chemistry.

A first epitaxial layer is grown on the at least one substrate in the first deposition chamber at the first location with the first independent chemical vapor deposition process chemistry. Any means for growing the first epitaxial layer on the at least one substrate can be used. A heater positioned inside or outside of the first deposition chamber is used to heat the growth surface of the at least one substrate. At least one CVD process gas is provided to the first deposition chamber at a flow rate that results in the deposition of a desired film by chemical vapor deposition. The at least one CVD process gas can be at least one MOCVD gas.

The first substrate carrier is transported after the first epitaxial layer is grown to a second location. In some methods, the heater associated with the first substrate carrier is transported along with the first substrate carrier. The first substrate carrier can be transported by numerous means such as by transportation along a track, rail, or a conveyor-type mechanism, which can also include belts, push-rods, and magnetically coupled drives such as magnetic linear motors. The first substrate carrier is then enclosed to form a second deposition chamber that maintains a second independent chemical vapor deposition process chemistry.

A second epitaxial layer is grown on top of the first epitaxial layer in the second deposition chamber at the second location with the second independent chemical vapor deposition process chemistry. Any means for growing the second epitaxial layer on the at least one substrate can be used. A heater positioned inside or outside of the second deposition chamber is used to heat the growth surface of the at least one substrate and CVD process gasses.

It is also possible to deposit multiple epitaxial layers, or a stack of layers, within each transport sequence, that is, in each chamber before the substrate carrier (loaded with substrates) is moved from one chamber to another chamber.

At least one CVD process gas is provided to the second deposition chamber at a flow rate that results in the deposition of a desired film by chemical vapor deposition. The at least one CVD process gas can be at least one MOCVD gas. The method can include configuring a gas distribution manifold to provide the desired CVD gases to each of the first and the second deposition chambers.

The method of forming multiple epitaxial layers on the substrate using the multi-chamber chemical vapor deposition system continues with a second rotatable substrate carrier. The second rotatable substrate carrier comprising at least one substrate at the first location is enclosed to form the first deposition chamber that maintains the first independent chemical vapor deposition process chemistry. The first epitaxial layer is then grown on substrates positioned on the second substrate carrier in the first deposition chamber at the first location with the first independent chemical vapor deposition process chemistry. The at least one substrate on the first and the second substrate carriers are typically processed simultaneously in time.

The method continues with the first substrate carrier being transported after the second epitaxial layer is grown to a third location. The first rotatable substrate carrier comprising at least one substrate is then enclosed at a third location to form a third deposition chamber that maintains a third independent chemical vapor deposition process chemistry. In some methods, the heater associated with the third substrate carrier is transported along with the third substrate carrier. The second rotatable substrate carrier is transported to the second location where it is enclosed to form the second deposition chamber that maintains the second independent chemical vapor deposition process chemistry. A third rotatable substrate carrier is transported to the first location where it is enclosed to form the first deposition chamber that maintains the first independent chemical vapor deposition process chemistry. The transporting of the first, second, and third substrate carriers can be performed simultaneously. In addition, deposition can be performed in the first, second, and third deposition chambers simultaneously. This method is continued for a forth and additions substrate carriers. As discussed before, not all chambers may be similar or used for CVD processes. Some chambers may be devoted exclusively to baking/heat up of the carrier, annealing prior to or following a process step, cool-down at the end of the process sequence or a surface modification step prior to or following a process step.

In other methods and systems according to the present teaching, the substrate carrier is not a rotatable carrier. Those skilled in the art will appreciate how to deposit and grow epitaxial layers in such systems or by such methods in accordance with the present teachings set forth hereinabove.

In some methods according to the present teaching, in-situ measurements of deposited material layers properties are performed during deposition. For example, in-situ pyrometry can be performed while growing at least one of the first and second epitaxial layers to monitor the growth temperate at the surface of the substrates. In addition, in-situ reflectometer can be preformed to measure film thickness and/or growth rate of the deposited films.

### Equivalents

While the applicant's teaching are described in conjunction with various embodiments, it is not intended that the applicant's teaching be limited to such embodiments. On the contrary, the applicant's teaching encompass various alternatives, modifications, and equivalents, as will be appreciated by those of skill in the art, which may be made therein without departing from the spirit and scope of the teaching.

What is claimed is:

1. A multi-chamber CVD processing system comprising:
a. a plurality of substrate carriers, each substrate carrier adapted to support at least one substrate;
b. a plurality of enclosures, each of the plurality of enclosures configured to form a deposition chamber enclosing one of the plurality of substrate carriers to maintain an independent environment for performing a processing step; and
c. a transport mechanism that transports each of the plurality of substrate carriers to each of the plurality of enclosures in discrete steps that allows processing steps to be performed in the plurality of enclosures for a predetermined time.

2. The multi-chamber CVD system of claim 1 which further comprises a plurality of heaters, each of the plurality of heaters corresponding to each of the plurality of enclosures.

3. The multi-chamber CVD system of claim 2 wherein each of the plurality of heaters is proximate to each of the plurality of substrate carriers when each of the plurality of substrate carriers is enclosed by the plurality of enclosures.

4. The multi-chamber CVD system of claim 1 wherein at least one of the plurality of enclosures comprises a physical enclosure.

5. The multi-chamber CVD system of claim 1 wherein at least one of the plurality of enclosures is movable relative at least one of the plurality of substrate carriers to form at least one of the plurality of deposition chambers.

6. The multi-chamber CVD system of claim 1 wherein at least one of the plurality of substrate carriers is movable relative to at least one of the plurality of enclosures to form at least one of the plurality of deposition chambers.

7. The multi-chamber CVD system of claim 1 wherein at least one of the plurality of enclosures and a corresponding one of the plurality of substrate carriers are both movable to form at least one of the plurality of deposition chambers.

8. The multi-chamber CVD system of claim 1 wherein at least one of the plurality of enclosures comprises a gas curtain that forms at least one boundary of the corresponding enclosure.

9. The multi-chamber CVD system of claim 1 wherein at least one of the plurality of enclosures comprises an in-situ measurement device.

10. The multi-chamber CVD system of claim 9 wherein the in-situ measurement device is selected from a pyrometer, reflectometer, deflectometer, ellipsometer, photoluminescence spectrometer, combination pyrometer/reflectometer, a combined deflectometer/reflectometer/temperature tool, and electroluminescence spectrometer.

11. The multi-chamber CVD system of claim 1 wherein the transport mechanism further comprises a plurality of heaters, each of the plurality of heaters being proximate to each of the plurality of substrate carriers.

12. The multi-chamber CVD system of claim 1 wherein the transport mechanism transports each of the plurality of substrate carriers to each of the plurality of enclosures on along a rail.

13. The multi-chamber CVD system of claim 1 wherein the transport mechanism transports each of the plurality of substrate carriers to each of the plurality of enclosures along a track.

14. The multi-chamber CVD system of claim 1 wherein the transport mechanism transports each of the plurality of substrate carriers to each of the plurality of enclosures using a conveyor.

15. The multi-chamber CVD system of claim 1 wherein the transport mechanism transports each of the plurality of substrate carriers to each of the plurality of enclosures in a linear path.

16. The multi-chamber CVD system of claim 1 wherein the transport mechanism transports each of the plurality of substrate carriers to each of the plurality of enclosures in a non-linear path.

17. The multi-chamber CVD system of claim 1 wherein the transport mechanism transports each of the plurality of substrate carriers to each of the plurality of enclosures in a circular path.

18. The multi-chamber CVD system of claim 1 wherein the transport mechanism transports each of the plurality of substrate carriers to each of the plurality of enclosures in an oval path.

19. The multi-chamber CVD system of claim 1 wherein the transport mechanism is coupled to an automated substrate handling mechanism that performs at least one of loading and unloading of substrates to and from the plurality of substrate carriers.

20. The multi-chamber CVD system of claim 1 wherein at least one of the plurality of substrate carriers is a rotatable substrate carrier.

21. The multi-chamber CVD system of claim 1 wherein at least one of the plurality of substrate carriers comprises a susceptor and a substrate carrier.

22. The multi-chamber CVD system of claim 1 wherein at least one of the plurality of substrate carriers is a susceptorless substrate carrier.

23. The multi-chamber CVD system of claim 1 wherein at least one of the plurality of substrate carriers is a planetary motion carrier.

24. The multi-chamber CVD system of claim 1 which further comprises a gas distribution injector which injects at least one precursor gas, wherein at least one precursor gas flows through the injector in a direction that is substantially perpendicular to the substrate carrier.

25. The multi-chamber CVD system of claim 1 further comprising a gas distribution injector which injects at least one precursor gas, wherein the at least one precursor gas flows through the injector in a direction that is substantially parallel to the substrate carrier.

26. The multi-chamber CVD system of claim 1 further comprising a gas distribution injector which injects at least one precursor gas, wherein at least one precursor gas flows through the injector in a direction that is substantially perpendicular to the substrate carrier and wherein at least one precursor gas flows through the injector in a direction that is substantially parallel to the substrate carrier.

27. A multi-chamber CVD process system comprising:
a. a plurality of substrate carriers, each substrate carrier adapted to support at least one substrate;
b. a plurality of enclosures, each of the plurality of enclosures configured to form a deposition chamber enclosing one of the plurality of substrate carriers to maintain an independent environment for performing a processing step;
c. a plurality of heaters that each heat a corresponding one of the plurality of substrates to a desired process temperature for performing the processing steps; and
d. a transport mechanism that transports each of the plurality of substrate carriers to each of the plurality of enclosures in discrete steps that allows processing steps to be performed in the plurality of enclosures for a predetermined time.

28. The multi-chamber CVD system of claim 27 wherein the transport mechanism further comprises a plurality of heaters, each of the plurality of heaters being proximate to each substrate carrier.

29. The multi-chamber CVD system of claim 27 wherein at least one of the plurality of heaters is positioned inside a corresponding one of the plurality of deposition chambers proximate to the substrate carrier.

30. The multi-chamber CVD system of claim 27 wherein at least one of the plurality of heaters has a first portion that is positioned inside a corresponding one of the plurality of deposition chambers proximate to the substrate carrier and a second portion that is positioned outside of the corresponding one of the plurality of deposition chambers.

31. The multi-chamber CVD system of claim 27 wherein the transport mechanism transports at least one of the plurality of heaters along with a corresponding one of the plurality of substrate carriers.

32. The multi-chamber CVD system of claim 27 wherein each of the plurality of heaters comprises a first and second section that define a gap for passing the plurality of substrate carriers.

33. The multi-chamber CVD system of claim 27 wherein at least one of the plurality of heaters comprises a resistive heater.

34. The multi-chamber CVD system of claim 27 wherein at least one of the plurality of heaters comprises an RF heater.

35. The multi-chamber CVD system of claim 27 wherein at least one of the plurality of substrate carriers is a rotatable substrate carrier.

36. The multi-chamber CVD system of claim 27 wherein at least one of the plurality of substrate carriers comprises a susceptor and a substrate carrier.

37. The multi-chamber CVD system of claim 27 wherein at least one of the plurality of substrate carriers is a susceptorless substrate carrier.

38. The multi-chamber CVD system of claim 27 wherein at least one of the plurality of substrate carriers is a planetary motion carrier.

39. The multi-chamber CVD system of claim 27 wherein at least one of the plurality of enclosures comprises an in-situ measurement device.

40. The multi-chamber CVD system of claim 39 wherein the in-situ measurement device is selected from a pyrometer, reflectometer, deflectometer, ellipsometer, photoluminescence spectrometer, combination pyrometer/reflectometer, a combined deflectometer/reflectometer/temperature tool, and electroluminescence spectrometer.

41. The multi-chamber CVD system of claim 27 wherein the transport mechanism transports each of the plurality of substrate carriers to each of the plurality of enclosures using one of a track, a conveyor, a rail, a tank tread, or any combination thereof

42. The multi-chamber CVD system of claim 27 wherein the transport mechanism transports each of the plurality of substrate carriers to each of the plurality of enclosures in a linear path.

43. The multi-chamber CVD system of claim 27 wherein the transport mechanism transports each of the plurality of substrate carriers to each of the plurality of enclosures in a non-linear path.

44. The multi-chamber CVD system of claim 27 wherein the transport mechanism is coupled to an automated substrate handling mechanism that performs at least one of loading and unloading of substrates to and from the plurality of substrate carriers.

45. The multi-chamber CVD system of claim 27 further comprising a gas distribution injector which injects at least one precursor gas, wherein the at least one precursor gas flows through the injector in a direction that is substantially perpendicular to the substrate carrier.

46. The multi-chamber CVD system of claim 27 further comprising a gas distribution injector which injects at least one precursor gas, wherein the at least one precursor gas flows through the injector in a direction that is substantially parallel to the substrate carrier.

47. The multi-chamber CVD system of claim 27 further comprising a gas distribution injector which injects at least one precursor gas, wherein at least one precursor gas flows through the injector in a direction that is substantially perpendicular to the substrate carrier and wherein at least one precursor gas flows through the injector in a direction that is substantially parallel to the substrate carrier.

48. A method of forming multiple epitaxial layers on a substrate using a multi-chamber chemical vapor deposition system, the method comprising:
a. enclosing a first substrate carrier comprising at least one substrate at a first location to form a first deposition chamber that maintains a first independent environment;
b. growing a first epitaxial layer on the at least one substrate in the first deposition chamber at the first location with the first independent environment;
c. transporting the first substrate carrier after the first epitaxial layer is grown to a second location and enclosing the first substrate carrier to form a second deposition chamber that maintains a second independent environment; and
d. growing a second epitaxial layer on top of the first epitaxial layer in the second deposition chamber at the second location with the second independent environment.

49. The method of claim 48 further comprising:
a. enclosing a second substrate carrier comprising at least one substrate at the first location to form the first deposition chamber that maintains the first independent environment; and
b. growing the first epitaxial layer on the at least one substrate on the second substrate carrier in the first deposition chamber at the first location with the first independent environment.

50. The method of claim 49 wherein the at least one substrate on the first and the second substrate carriers are processed simultaneously in time.

51. The method of claim 48 wherein the enclosing the first substrate carrier to form the first and the second deposition chambers comprises moving a chamber over the first substrate carrier to isolate a respective one of the first and second chemical vapor deposition process chemistry inside the first and the second deposition chambers.

52. The method of claim 48 wherein the enclosing the first substrate carrier to form the first and the second deposition chambers comprises moving the first substrate carrier into a chamber to isolate a respective one of the first and second environment inside the first and the second deposition chambers.

53. The method of claim 48 wherein the enclosing the first substrate carrier to form the first and the second deposition chambers comprising forming gas curtains to isolate a respective one of the first and second environment.

54. The method of claim 48 wherein at least one of the first and the second independent chemical vapor deposition process chemistries is established using a heater that is fixed inside a corresponding one of the first and second process chambers.

55. The method of claim 48 wherein at least one of the first and the second environments is established using a heater that is fixed to a corresponding one of the first and second substrate carrier so that it moves with the corresponding one of the first and second substrate carrier.

56. The method of claim 48 wherein the transporting of the first substrate carrier to a second location comprises transporting the first substrate carrier along at least one of a track, rail, or conveyor, or any combination thereof

57. The method claim 48 wherein the transporting of the first substrate carrier to a second location comprises transporting the first substrate carrier along a linear path.

58. The method claim 48 wherein the transporting of the first substrate carrier to a second location comprises transporting the first substrate carrier along a non-linear path.

59. The method of claim 48 further comprising translating the first substrate carrier.

60. The method of claim 48 further comprises performing an in-situ measurement while growing at least one of the first and second epitaxial layers.

61. The method of claim 60 wherein the in-situ measurement is performed using a device selected from a pyrometer, reflectometer, deflectometer, ellipsometer, photoluminescence spectrometer, combination pyrometer/reflectometer, a combined deflectometer/reflectometer/temperature tool, and electroluminescence spectrometer.

62. The method of claim 48 wherein at least one of the plurality of substrate carriers is a rotatable substrate carrier.

63. The method of claim 48 wherein at least one of the plurality of substrate carriers comprises a susceptor and a substrate carrier.

64. The method of claim 48 wherein at least one of the plurality of substrate carriers is a susceptorless substrate carrier.

65. The method of claim 48 wherein at least one of the plurality of substrate carriers is a planetary motion carrier.

66. The method of claim 48 further comprising gas distribution injection of at least one precursor gas, wherein the at least one precursor gas is injected in a direction that is substantially perpendicular to the substrate carrier.

67. The method of claim 48 further comprising gas distribution injection of at least one precursor gas, wherein the at least one precursor gas is injected in a direction that is substantially parallel to the substrate carrier.

68. The method of claim 48 further comprising gas distribution injection of at least one precursor gas, wherein at least one precursor gas is injected in a direction that is substantially perpendicular to the substrate carrier and wherein at least one precursor gas is injected in a direction that is substantially parallel to the substrate carrier.

69. A multi-chamber chemical vapor deposition system comprising:
a. a means for enclosing a plurality of substrate carriers which support at least one substrate at a plurality of fixed locations to form a plurality of deposition chambers that each maintain an independent environment;
b. a means for growing an epitaxial layer on the at least one substrate supported by the plurality of substrate carriers in the plurality of deposition chambers that are each maintaining the independent environment; and
c. a means for transporting the plurality of substrate carriers between the plurality of deposition chambers in discrete steps.

70. The multi-chamber chemical vapor deposition system of claim 69 which further comprises means for rotating at least one of the plurality of substrate carriers.
